(19) United States
(12) Patent Application Publication
(10) Pub. No.: US 2026/0271455 A1
(43) Pub. Date: Sep. 10, 2026

(54) TRANSPARENT DISPLAY MODULE AND MANUFACTURING METHOD THEREOF

(71) Applicant: INGENTEC CORPORATION, Miaoli County (TW)

(72) Inventors: Chia-Pin WANG, Miaoli County (TW); Ai-Sen LIU, Miaoli County (TW); Hsiang-An FENG, Miaoli County (TW); Ya-Li CHEN, Miaoli County (TW)

(21) Appl. No.: 19/372,235

(22) Filed: Oct. 28, 2025

(30) Foreign Application Priority Data
Mar. 5, 2025 (TW) 114108022

(51) Int. Cl. H10H 29/49; H10H 29/01

(52) U.S. Cl. CPC H10H 29/49; H10H 29/012

(57) ABSTRACT

A transparent display module includes a transparent substrate, a plurality of light emitting diode elements, a first protective layer, a circuit structure, a plurality of integrated circuit elements and a second protective layer. The transparent substrate has a first surface and a second surface which are opposite to each other. The light emitting diode elements are disposed on the first surface. The first protective layer is connected to the first surface. The circuit structure is connected to the second surface. The integrated circuit elements are disposed on a surface away from the transparent substrate of the circuit structure. The second protective layer is connected to the surface of the circuit structure.

### RELATED APPLICATIONS

This application claims priority to Taiwan Application Serial Number 114108022, filed March 05, 2025, which is herein incorporated by reference.

### BACKGROUND

### Technical Field

The present disclosure relates to a transparent display module and a manufacturing method thereof. More particularly, the present disclosure relates to a transparent display module and a manufacturing method thereof, which have a good transparency.

### DESCRIPTION OF RELATED ART

The conventional display module electrically connects light emitting diode element to integrated circuit element to achieve the effect of regulating the light emission of the light emitting diodes element. The conventional display module is wired on a substrate surface to form a circuit structure between the light emitting diode element and the integrated circuit element. However, even if the display module uses a transparent substrate, the aforementioned circuit structure will still block light from passing through the display module, resulting in poor transparency of the display module. The conventional display module is not favorable to the application in places requiring high transparency, such as glass exterior walls or display windows.

### SUMMARY

According to one aspect of the present disclosure, a transparent display module includes a transparent substrate, a plurality of light emitting diode elements, a first protective layer, a circuit structure, a plurality of integrated circuit elements and a second protective layer. The transparent substrate has a first surface and a second surface which are opposite to each other, and the transparent substrate includes a first wiring structure and a second wiring structure. The first wiring structure is passed through the first surface towards the second surface. The second wiring structure is disposed on the first surface. The light emitting diode elements are disposed on the first surface, and the light emitting diode elements are electrically connected to the first wiring structure and the second wiring structure. The first protective layer is connected to the first surface, and the light emitting diode elements are embedded in the first protective layer. The circuit structure is connected to the second surface, the transparent substrate is located between the first protective layer and the circuit structure, the circuit structure includes a third wiring structure, and the third wiring structure is electrically connected to the first wiring structure. The integrated circuit elements are disposed on a surface away from the transparent substrate of the circuit structure, and the integrated circuit elements are electrically connected to the third wiring structure. The second protective layer is connected to the surface of the circuit structure, the circuit structure is located between the transparent substrate and the second protective layer, and the integrated circuit elements are imbedded in the second protective layer.

According to another aspect of the present disclosure, a manufacturing method of a transparent display module includes the following steps. A first wiring structure and a second wiring structure are formed at a transparent substrate, the transparent substrate has a first surface and a second surface which are opposite to each other, the first wiring structure is passed through the first surface towards the second surface, and the second wiring structure is disposed on the first surface. A circuit structure is formed on the second surface, the circuit structure includes a third wiring structure, and the third wiring structure is electrically connected to the first wiring structure. A plurality of light emitting diode elements are disposed on the first surface, and the light emitting diode elements are electrically connected to the first wiring structure and the second wiring structure. A plurality of integrated circuit elements are disposed on a surface away from the transparent substrate of the circuit structure, and the integrated circuit elements are electrically connected to the third wiring structure. A first protective layer is formed on the first surface, the light emitting diode elements are embedded in the first protective layer, and the transparent substrate is located between the first protective layer and the circuit structure. A second protective layer is formed on the surface of the circuit structure, the circuit structure is located between the transparent substrate and the second protective layer, and the integrated circuit elements are imbedded in the second protective layer so as to obtain the transparent display module.

### BRIEF DESCRIPTION OF THE DRAWINGS

The present disclosure can be more fully understood by reading the following detailed description of the embodiment, with reference made to the accompanying drawings as follows:

FIG. 1 is a top schematic view of a transparent display module according to one embodiment of the present disclosure.

FIG. 2 is a cross-sectional schematic view of the transparent display module along line 2-2 of FIG. 1.

FIG. 3 is a flow chart of a manufacturing method of a transparent display module according to one embodiment of the present disclosure.

### DETAILED DESCRIPTION

A number of examples of the present disclosure will be described below with reference to the accompanying drawings. The following description will include many practical details in order to be clear and specific. The reader, however, should understand that those practical details are not intended to be restrictive of the scope of the invention; in other words, the practical details are not essential to some embodiments of the invention.

Besides, for the sake of simplicity of the drawings, some conventional or commonly used structures and elements are drawn only schematically in the drawings, and repeated elements may be indicated by the same reference numeral or similar reference numerals.

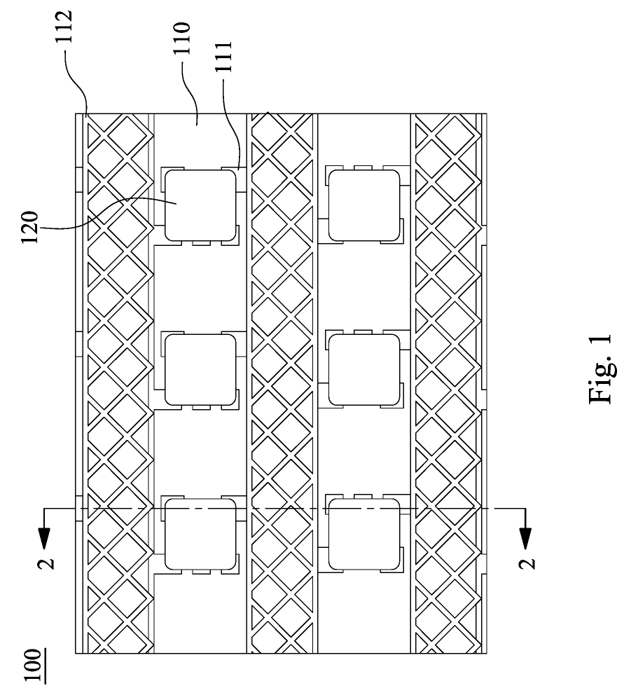

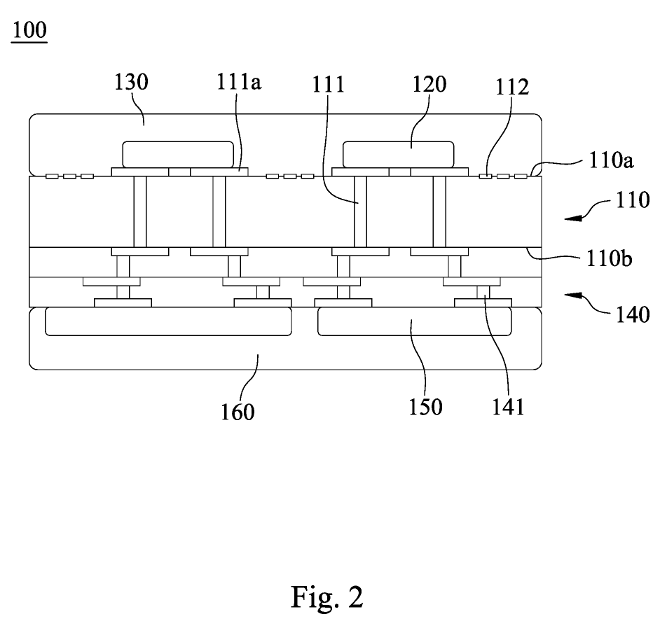

Please refer to FIG. 1 and FIG. 2, FIG. 1 is a top schematic view of a transparent display module 100 according to one embodiment of the present disclosure, and FIG. 2 is a cross-sectional schematic view of the transparent display module 100 along line 2-2 of FIG. 1. The transparent display module 100 includes a transparent substrate 110, a plurality of light emitting diode elements 120, a first protective layer 130, a circuit structure 140, a plurality of integrated circuit elements 150 and a second protective layer 160.

The transparent substrate 110 has a first surface 110a and a second surface 110b, which are opposite to each other, and the transparent substrate 110 includes a first wiring structure 111 and a second wiring structure 112, the first wiring structure 111 is passed through the first surface 110a towards the second surface 110b, and the second wiring structure 112 is disposed on the first surface 110a. Therefore, the first wiring structure 111 and the second wiring structure 112 can respectively provide the signal and the current transmission to avoid mutual interference, but the present disclosure is not limited thereto.

In detail, the transparent display module 100 can be a through glass via (TGV) substrate, which has the good light transmittance and the through holes, the through holes can be used for disposing the first wiring structure 111, and the detail of the structure and location of the first wiring structure 111 can be adjusted on demands, so that the present disclosure is not limited thereto.

The second wiring structure 112 located on the first surface 110a is formed in a grid arranged shape or a straight line arranged shape. Alternatively, the second wiring structure 112 can include a plurality of wires (its reference numeral is omitted), and a width of each of the wires is 10 μm to 100 μm. By adjusting the arrangement of the second wiring structure 112 or the width of the wires, the problem of blocked light caused by the second wiring structure 112 can be reduced, thereby improving the transparency of the transparent display module 100.

The light emitting diode elements 120 are disposed on the first surface 110a, and the light emitting diode elements 120 are electrically connected to the first wiring structure 111 and the second wiring structure 112. For example, the first wiring structure 111 can include a plurality of conductive pads 111a, and the light emitting diode elements 120 can be electrically connected to the first wiring structure 111 via the conductive pads 111a. Furthermore, a number of the conductive pads 111a can be 1 time to 4 times of a number of the light emitting diode elements 120. Therefore, it is favorable to improve the convenience in installing the light emitting diode elements 120.

The first protective layer 130 is connected to the first surface 110a, and the light emitting diode elements 120 are embedded in the first protective layer 130. Furthermore, the first protective layer 130 can be made of a transparent material so as to avoid that the light emitting effect of the light emitting diode element 120 to be affected while providing good protection.

The circuit structure 140 is connected to the second surface 110b, so that the transparent substrate 110 is located between the first protective layer 130 and the circuit structure 140. The circuit structure 140 includes a third wiring structure 141, and the third wiring structure 141 is electrically connected to the first wiring structure 111. In detail, the circuit structure 140 can be a redistribution layer (RDL) structure, which can form the desired third wiring structure 141 by setting a patterned circuit layer, through holes and a dielectric layer, and the number and structure of the patterned circuit layer, the through holes and the dielectric layer can be adjusted according to requirements, so that the present disclosure is not limited thereto.

The integrated circuit elements 150 are disposed on a surface (its reference numeral is omitted) away from the transparent substrate 110 of the circuit structure 140, and the integrated circuit elements 150 are electrically connected to the third wiring structure 141. In detail, each of the integrated circuit elements 150 can be a driving integrated circuit element or a controlling integrated circuit element, and the present disclosure is not limited thereto.

The second protective layer 160 is connected to the surface of the circuit structure 140, so that the circuit structure 140 is located between the transparent substrate 110 and the second protective layer 160, and the integrated circuit elements 150 are imbedded in the second protective layer 160. Furthermore, the second protective layer 160 can be made of a transparent material so as to avoid that the transparency of the transparent display module 100 to be affected while providing good protection.

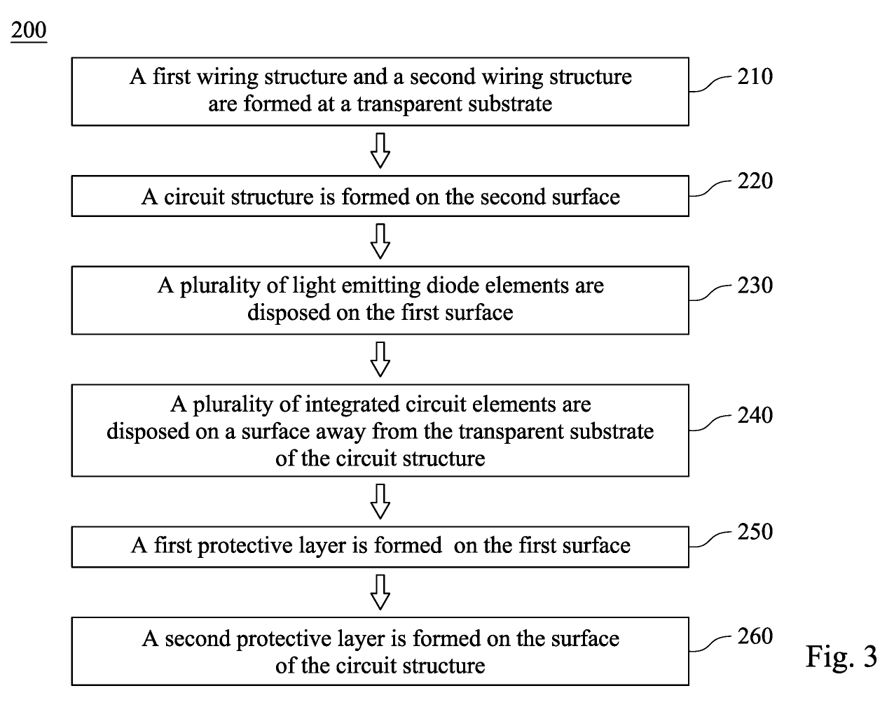

Please refer to FIG. 3, FIG. 3 is a flow chart of a manufacturing method of a transparent display module 200 according to one embodiment of the present disclosure. The manufacturing method of the transparent display module 200 includes step 210, step 220, step 230, step 240, step 250 and step 260.

Please refer to FIG. 1 to FIG. 3. In the step 210, the first wiring structure 111 and the second wiring structure 112 are formed at the transparent substrate 110, the transparent substrate 100 has the first surface 110a and the second surface 110b which are opposite to each other, the first wiring structure 111 is passed through the first surface 110a towards the second surface 110b, and the second wiring structure 112 is disposed on the first surface 110a. In detail, the first wiring structure 111 can be formed by utilizing the through holes of the transparent substrate 110, and the conductive pads 111a may be disposed on the first surface 110a for subsequent electrical connection. The second wiring structure 112 can be made by adopting printing technology, and the second wiring structure 112 located on the first surface can be formed in the grid arranged shape or the straight line arranged shape, but the present disclosure is not limited thereto.

In step 220, the circuit structure 140 is formed on the second surface 110b, the circuit structure 140 includes the third wiring structure 141, and the third wiring structure 141 is electrically connected to the first wiring structure 111. The third wiring structure 141 of the circuit structure 140 can be formed by repeatedly stacking patterned circuit layers and dielectric layers, and the number and the structure of the patterned circuit layers and the dielectric layers can be determined according to the types of elements electrically connected.

In step 230, the light emitting diode elements 120 are disposed on the first surface 110a, and the light emitting diode elements 120 are electrically connected to the first wiring structure 111 and the second wiring structure112. Therefore, the first wiring structure 111 and the second wiring structure 112 can respectively provide the signal and the current transmission to avoid mutual interference.

In step 240, the integrated circuit elements 150 are disposed on the surface away from the transparent substrate 110 of the circuit structure 140, and the integrated circuit elements 150 are electrically connected to the third wiring structure 141. Base on the large number of the pins of the integrated circuit elements 150, by disposing the integrated circuit elements 150 on the circuit structure 140, the third wiring structure 141 can be adjusted according to the distribution of the pins of the integrated circuit elements 150, thereby facilitating the completion of the electrical connection of the integrated circuit elements 150.

In the step 250, the first protective layer 130 is formed on the first surface 110a, the light emitting diode elements 120 are embedded in the first protective layer 130, and the transparent substrate 110 is located between the first protective layer 130 and the circuit structure 140. In the step 260, the second protective layer 160 is formed on the surface of the circuit structure 140, the circuit structure 140 is located between the transparent substrate 110 and the second protective layer 160, and the integrated circuit elements 150 are imbedded in the second protective layer 160 so as to obtain the transparent display module 100. Therefore, the first protective layer 130 and the second protective layer 160 can provide a good protection, and the first protective layer 130 and the second protective layer 160 can be made of a transparent material, so as to avoid affecting the transparency of the transparent display module 100.

It should be noted that, the transparent substrate 110, the light emitting diode elements 120, the first protective layer 130, the circuit structure 140, the integrated circuit elements 150, the second protective layer 160 are produced by the manufacturing method of the transparent display module 200, the structure and the size thereof are the same or similar to the aforementioned transparent display module 100, and will not be described again herein.

In conclusion, according to the transparent display module and the manufacturing method of the transparent display module of the present disclosure, by disposing the transparent substrate, the first protective layer, the circuit structure and the second protective layer, and utilizing the first wiring structure, the second wiring structure and the third wiring structure for electrical configuration, so that the transparent display module of the present disclosure has a good transparency. Moreover, the transparent display module of the present disclosure has a specific structure design, so that the transparent display module can be cut into strips according to the requirement, thereby improving space utilization of the transparent display module.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A transparent display module, comprising:
a transparent substrate having a first surface and a second surface which are opposite to each other, wherein the transparent substrate comprises:
a first wiring structure passed through the first surface towards the second surface; and
a second wiring structure disposed on the first surface;
a plurality of light emitting diode elements disposed on the first surface, wherein the light emitting diode elements are electrically connected to the first wiring structure and the second wiring structure;
a first protective layer connected to the first surface, wherein the light emitting diode elements are embedded in the first protective layer;
a circuit structure connected to the second surface, wherein the transparent substrate is located between the first protective layer and the circuit structure, the circuit structure comprises a third wiring structure, and the third wiring structure is electrically connected to the first wiring structure;
a plurality of integrated circuit elements disposed on a surface away from the transparent substrate of the circuit structure, wherein the integrated circuit elements are electrically connected to the third wiring structure; and
a second protective layer connected to the surface of the circuit structure, wherein the circuit structure is located between the transparent substrate and the second protective layer, and the integrated circuit elements are imbedded in the second protective layer.

2. The transparent display module of claim 1, wherein the first wiring structure comprises a plurality of conductive pads, and the light emitting diode elements are electrically connected to the first wiring structure via the conductive pads.

3. The transparent display module of claim 2, wherein a number of the conductive pads is 1 time to 4 times of a number of the light emitting diode elements.

4. The transparent display module of claim 1, wherein the second wiring structure located on the first surface is formed in a grid arranged shape or a straight line arranged shape.

5. The transparent display module of claim 1, wherein the second wiring structure comprises a plurality of wires, and a width of each of the wires is 10 μm to 100 μm.

6. The transparent display module of claim 1, wherein the first protective layer is made of a transparent material.

7. The transparent display module of claim 1, wherein the second protective layer is made of a transparent material.

8. The transparent display module of claim 1, wherein each of the integrated circuit elements is a driving integrated circuit element or a controlling integrated circuit element.

9. A manufacturing method of a transparent display module, comprising:
forming a first wiring structure and a second wiring structure at a transparent substrate, wherein the transparent substrate has a first surface and a second surface which are opposite to each other, the first wiring structure is passed through the first surface towards the second surface, and the second wiring structure is disposed on the first surface;
forming a circuit structure on the second surface, wherein the circuit structure comprises a third wiring structure, and the third wiring structure is electrically connected to the first wiring structure;
disposing a plurality of light emitting diode elements on the first surface, wherein the light emitting diode elements are electrically connected to the first wiring structure and the second wiring structure;
disposing a plurality of integrated circuit elements on a surface away from the transparent substrate of the circuit structure, wherein the integrated circuit elements are electrically connected to the third wiring structure;
forming a first protective layer on the first surface, wherein the light emitting diode elements are embedded in the first protective layer, and the transparent substrate is located between the first protective layer and the circuit structure; and
forming a second protective layer on the surface of the circuit structure, wherein the circuit structure is located between the transparent substrate and the second protective layer, and the integrated circuit elements are imbedded in the second protective layer so as to obtain the transparent display module.

10. The manufacturing method of the transparent display module of claim 9, wherein the first wiring structure comprises a plurality of conductive pads, and the light emitting diode elements are electrically connected to the first wiring structure via the conductive pads.

11. The manufacturing method of the transparent display module of claim 10, wherein a number of the conductive pads is 1 time to 4 times of a number of the light emitting diode elements.

12. The manufacturing method of the transparent display module of claim 9, wherein the second wiring structure located on the first surface is formed in a grid arranged shape or a straight line arranged shape.

13. The manufacturing method of the transparent display module of claim 9, wherein the second wiring structure comprises a plurality of wires, and a width of each of the wires is 10 μm to 100 μm.

14. The manufacturing method of the transparent display module of claim 9, wherein the first protective layer is made of a transparent material.

15. The manufacturing method of the transparent display module of claim 9, wherein the second protective layer is made of a transparent material.
